(19) United States
(12) Patent Application Publication
(10) Pub. No.: US 2025/0007491 A1
(43) Pub. Date: Jan. 2, 2025

(54) ACOUSTIC WAVE DEVICES AND MODULES COMPRISING SAME

(71) Applicant: Sanan Japan Technology Corporation, Tokyo (JP)

(72) Inventors: Hiroomi KANEKO, Tokyo (JP); Shinichi SHIOI, Tokyo (JP)

(73) Assignee: Sanan Japan Technology Corporation, Tokyo (JP)

(21) Appl. No.: 18/758,530

(22) Filed: Jun. 28, 2024

(30) Foreign Application Priority Data
Jun. 29, 2023 (JP) 2023-106759

(51) Int. Cl. H03H 9/02; H03H 9/25

(52) U.S. Cl. CPC H03H 9/02992; H03H 9/02543; H03H 9/02818; H03H 9/25

(57) ABSTRACT

An acoustic wave device includes a piezoelectric substrate, a support substrate bonded on the piezoelectric substrate, and a resonator formed on the other side of the support substrate on the piezoelectric substrate generates main-mode wave and transverse-mode wave when power is applied. The resonator includes a first bus bar, a second bus bar opposed to the first bus bar, a plurality of first electrode fingers connected to the side of the second bus bar in the first bus bar, a plurality of second electrode fingers connected to the side of the first bus bar in the second bus bar, a plurality of first dummy electrodes connected to the side of the second bus bar in the first bus bar, and a plurality of second dummy electrodes connected to the side of the first bus bar in the second bus bar.

### CROSS-REFERENCE TO RELATED APPLICATION(S)

This application claims priority to Japanese Application No. 2023-106759, filed Jun. 29, 2023, which are incorporated herein by reference, in their entirety, for any purpose.

### BACKGROUND OF THE INVENTION

### Field of the Invention

The present disclosure relates to an acoustic wave device and a module including the acoustic wave device.

### Background Art

Patent Document 1 (JP 2018-174595) discloses an acoustic wave device. A wide-width region of the electrode finger or the like is provided in the acoustic wave device. Such a wide-width region can suppress transverse-mode spurious.

However, transverse-mode spurious cannot be sufficiently suppressed by only the wide-width regions or the like in the acoustic wave device described in Patent Document 1. Therefore, it is desired to more certainly suppress transverse-mode spurious.

### SUMMARY OF THE INVENTION

Some examples described herein may address the above-described problems. Some examples described herein may have an object to provide an acoustic wave device capable of suppressing transverse-mode spurious more certainly, and a module including the acoustic wave device.

In some examples, an acoustic wave device includes a piezoelectric substrate, a support substrate bonded on the piezoelectric substrate, and a resonator formed on the other side of the support substrate on the piezoelectric substrate generates main-mode wave and transverse-mode wave when power is applied. The resonator includes a first bus bar, a second bus bar opposed to the first bus bar, a plurality of first electrode fingers connected to the side of the second bus bar in the first bus bar, a plurality of second electrode fingers connected to the side of the first bus bar in the second bus bar, a plurality of first dummy electrodes connected to the side of the second bus bar in the first bus bar and opposed to the plurality of second electrode fingers, and a plurality of second dummy electrodes connected to the side of the first bus bar in the second bus bar and opposed to the plurality of first electrode fingers. The distal ends of the plurality of first electrode fingers have first distal side wide-width regions, the distal ends of the plurality of second electrode fingers have second distal side wide-width regions, and the plurality of first dummy electrodes are formed so as to be gradually shorten from one end portion to the other end portion of the first bus bar.

### BRIEF DESCRIPTION OF THE DRAWING

FIG. 1 is a cross-sectional view of an acoustic wave device according to a first embodiment.

FIG. 2 is a diagram illustrating an example of a resonator of the acoustic wave device according to the first embodiment.

FIG. 3 is an enlarged view of a portion A and B and C and D of FIG. 2.

FIG. 4 is an enlarged view of a portion E and F of FIG. 3.

FIG. 5 is a diagram illustrating the characteristics of the resonator of the acoustic wave device according to the first embodiment and a resonator of the comparative example.

FIG. 6 is a diagram illustrating the characteristics of the resonator including bus bar with the same inclined section as the resonator of the acoustic wave device according to the first embodiment and no wide-width regions with the same length of the dummy electrodes, and the resonator of the comparative example.

FIG. 7 is a diagram illustrating the characteristics of the resonator including bus bar with the different inclined section from the resonator of the acoustic wave device according to the first embodiment and no wide-width regions with the different length of the dummy electrodes, and the resonator of the comparative example.

FIG. 8 is a diagram illustrating the characteristics of the resonator including bus bar with the same inclined section as the resonator of the acoustic wave device according to the first embodiment and the different wide-width regions with the same length of the dummy electrodes, and the resonator of the comparative example.

FIG. 9 is a diagram illustrating the characteristics of the resonator including bus bar with the same inclined section as the resonator of the acoustic wave device according to the first embodiment and the different wide-width regions with the same length of the dummy electrodes, and the resonator of the comparative example.

FIG. 10 is a diagram illustrating an example of a resonator of the acoustic wave device according to the second embodiment.

FIG. 11 is an enlarged view of a portion A and B and C and D of FIG. 10.

FIG. 12 is a diagram illustrating the characteristics of the resonator including no wide-width regions with the same length of the dummy electrode, and the resonator of the comparative example.

FIG. 13 is a diagram illustrating the characteristics of the resonator including no wide-width regions with the different length of the dummy electrode, and the resonator of the comparative example.

FIG. 14 s a cross-sectional view of a module which an acoustic wave device according to a third embodiment is applied to.

### DETAILED DESCRIPTION

The embodiments will be described with reference to the accompanying drawings. In the drawings, the same or corresponding parts are denoted by the same reference numerals. Duplicate descriptions of such portions may be simplified or omitted.

### First Embodiment

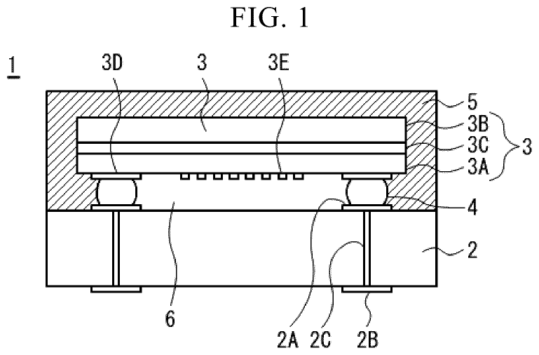

FIG. 1 is a cross-sectional view of an acoustic wave device according to a first embodiment.

As shown in FIG. 1, the acoustic wave device 1 includes a wiring substrate 2, a chip substrate 3, a plurality of bumps 4, and a sealing portion 5.

The wiring substrate 2 is a multilayer substrate made of resin. For example, the wiring substrate 2 is a low-temperature co-fired ceramic (LTCC) multilayer substrate includes a plurality of dielectric layers. For example, the wiring substrate 2 includes a passive element (not shown) such as a capacitor or an inductor.

In FIG. 1, the upper surface of the wiring substrate 2 is a component mounting surface. A plurality of conductive pads 2A are formed on the upper surface of the wiring substrate 2. The plurality of conductive pads 2A may be formed of copper for example. The lower surface of the wiring substrate 2 is an attachment surface to a mother substrate or the like. A plurality of conductive pads 2B are formed on the lower surface of the wiring substrate 2. The plurality of conductive pads 2B may be formed of copper for example. The plurality of inner conductors 2C are embedded in the wiring substrate 2. A plurality of inner conductors 2C are formed of copper for example. Each of the inner conductors 2C electrically connects the conductive pad 2A and the conductive pad 2B corresponding to each other.

The chip substrate 3 is opposed to the wiring substrate 2. The chip substrate 3 includes a piezoelectric substrate 3A, a support substrate 3B, and a low acoustic velocity layer 3C. The piezoelectric substrate 3A is disposed on the lower side of the chip substrate 3 in FIG. 1. The piezoelectric substrate 3A is formed of lithium tantalate, lithium niobate, or the like. The support substrate 3B is disposed on the upper side of the chip substrate 3. For example, the support substrate 3B is a polycrystalline substrate. For example, the polycrystalline substrate is C-axis oriented. For example, the support substrate 3B may be formed of silicon, alumina, spinel, quartz, glass, or the like. The low acoustic velocity layer 3C is disposed between the piezoelectric substrate 3A and the support substrate 3B. For example, the low acoustic velocity layer 3C is formed of silicon dioxide or the like.

A first filter and a second filter are formed on the main surface (lower surface in FIG. 1) of the chip substrate 3 for example. The first filter is a surface acoustic wave filter. The first filter is a transmission filter. The second filter is a surface acoustic wave filter. The second filter is a reception filter.

The transmission filter is formed such that an electrical signal of a desired frequency band can pass through. For example, the transmission filter includes a ladder-type filter including a plurality of series resonators and a plurality of parallel resonators.

The reception filter is formed such that an electrical signal of a desired frequency band can pass through. For example, the reception filter includes a ladder-type filter including a plurality of series resonators and a plurality of parallel resonators.

For example, the chip substrate 3 includes wiring patterns 3D and a plurality of electrodes 3E. The plurality of electrodes 3B are Interdigital Transducer (IDT) electrodes including comb-shaped electrode fingers.

Each of the plurality of bumps 4 is gold, a conductive adhesive solder, or the like. For example, the height of the bump 4 is 10 μm to 50 μm. Each of the plurality of bumps 4 electrically connects the conductive pads 2A and the wiring patterns 3A at corresponding positions.

The sealing portion 5 hermetically seals the chip substrate 3 together with the wiring substrate 2 while leaving a space 6 between the wiring substrate 2 and the chip substrate 3. For example, the sealing portion 5 is formed of an insulator such as synthetic resin. The synthetic resin is an epoxy resin, polyimide, or the like.

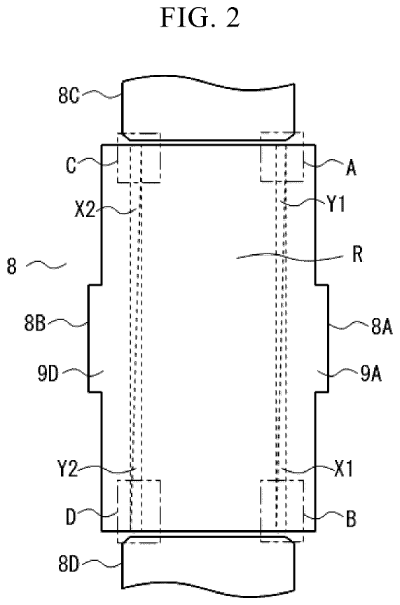

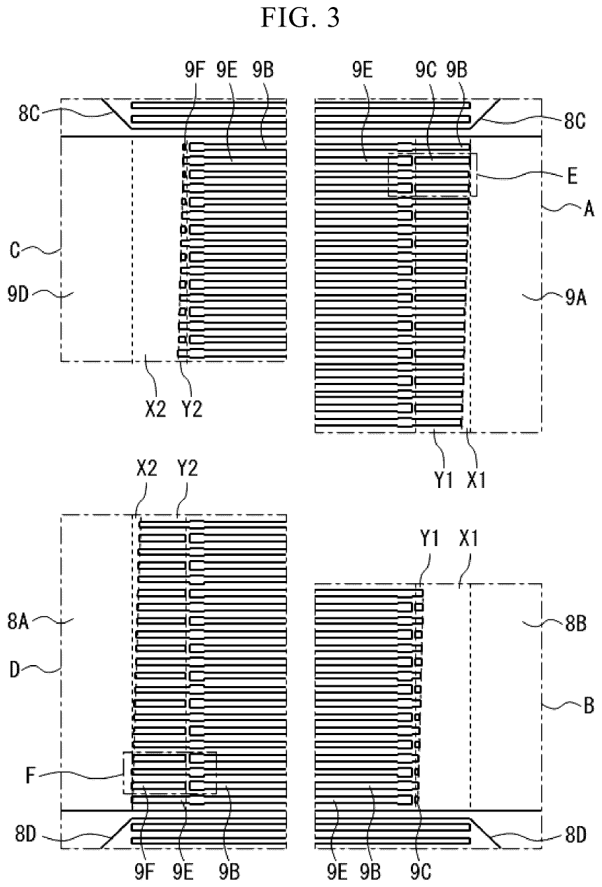

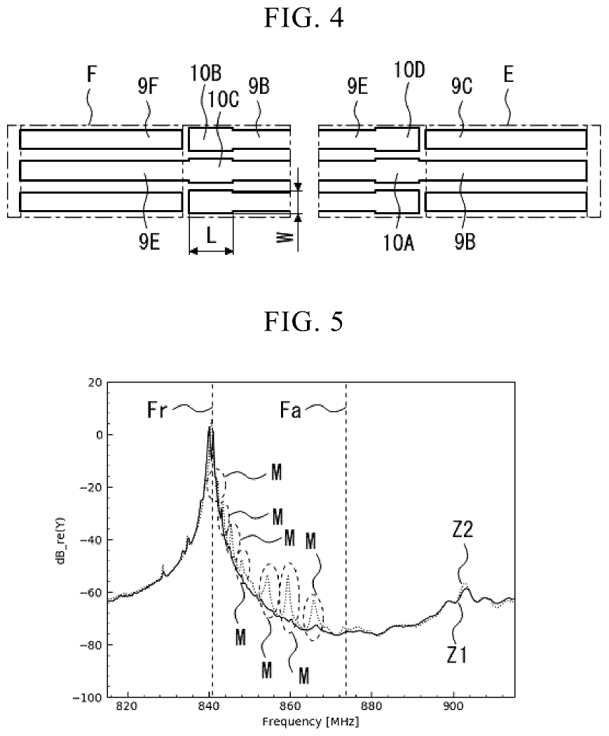

Next, an example of the resonator will be described with reference to FIG. 2 to FIG. 4. FIG. 2 is a diagram illustrating an example of the resonator of the acoustic wave device according to the first embodiment. FIG. 3 is an enlarged view of portions A, B, C, and D of FIG. 2. FIG. 4 is an enlarged view of portions E and F of FIG. 3.

A resonator 8 is a SAW (Surface Acoustic Wave) resonator in FIG. 2. The resonator 8 includes a first IDT electrode 8A, a second IDT electrode 8B, a first reflector 8C, and a second reflector 8D. The first IDT electrode 8A, the second IDT electrode 8B, the first reflector 8C, and the second reflector 8D are formed on the other side of the support substrate 3B in the piezoelectric substrate 3A (not shown in FIG. 2). The first IDT electrode 8A and the second IDT electrode 8B face each other. The first reflector 8C adjoins one side of the first IDT electrode 8A and the second IDT electrode 8B (upper side in FIG. 2). The second reflector 8D adjoins the other side of the first IDT electrode 8A and the second IDT electrode 8B (lower side in FIG. 2).

For example, the first IDT electrode 8A, the second IDT electrode 8B, the first reflector 8C, and the second reflector 8D are made of an alloy of aluminum and copper. For example, the first IDT electrode 8A, the second IDT electrode 8B, the first reflector 8C, and the second reflector 8D may be made of a suitable metal such as titanium, palladium, silver or an alloy thereof. For example, the first IDT electrode 8A, the second IDT electrode 8B, the first reflector 8C, and the second reflector 8D are made of a stacked metal film in which a plurality of metal layers are stacked. For example, the first IDT electrode 8A, the second IDT electrode 8B, the first reflector 8C, and the second reflector 8D are deposited and patterned in the same manner as the wiring pattern 3D (not shown in FIG. 2).

The first IDT electrode 8A, the second IDT electrode 8B, the first reflector 8C, and the second reflector 8D excite surface acoustic waves. Specifically, the first IDT electrode 8A, the second IDT electrode 8B, the first reflector 8C, and the second reflector 8D generate main-mode wave and transverse-mode wave when power is applied.

The first IDT electrode 8A includes a first bus bar 9A, a plurality of first electrode fingers 9B (not shown in FIG. 2), and a plurality of first dummy electrode 9C (not shown in FIG. 2). The second IDT electrode 8B includes a second bus bar 9D, a plurality of second electrode finger 9E (not shown in FIG. 2), and a plurality of second dummy electrode 9F (not shown in FIG. 2).

The first busbar 9A and the second bus bar 9D face each other. The first bus bar 9A includes a first inclined section X1. The first inclined section X1 is formed such that the other side of the first bus bar 9A is closer to the second bus bar 9D. The second bus bar 9D includes a second inclined section X2. The second inclined section X2 is formed such that one side of the second bus bar 9D is closer to the first bus bar 9A.

The plurality of first electrode fingers 9B are connected to the side of the second bus bar 9D in the first bus bar 9A. The plurality of first electrode fingers 9B are longitudinally aligned. The plurality of first electrode fingers 9B are formed so as to extend from the first bus bar 9A to the electrode finger region R. The plurality of second electrode fingers 9E are connected to the side of the first bus bar 9A in the second bus bar 9D. The plurality of second electrode fingers 9E are longitudinally aligned. The plurality of second electrode fingers 9E are formed so as to extend from the second bus bar 9D to the electrode finger region R.

The plurality of first dummy electrodes 9C are connected to the side of the second bus bar 9D in the first busbar 9A. The plurality of first dummy electrodes 9C are formed in a first dummy electrode region Y1. The plurality of second dummy electrodes 9F are connected to the side of the first bus bar 9A in the second bus bar 9D. The plurality of second dummy electrodes 9F are formed in a second dummy electrode region Y2.

As shown in FIG. 3, the plurality of first dummy electrodes 9C face the plurality of second electrode fingers 9E, respectively. The plurality of first dummy electrodes 9C are formed so as to gradually shorten from one end portion to the other end portion of the first inclined section X1 of the first bus bar 9A. The plurality of second dummy electrodes 9F face the plurality of first electrode fingers 9B, respectively. The plurality of second dummy electrodes 9F are formed so as to gradually lengthen from one end portion to the other end portion of the second inclined section X2 of the second bus bar 9D in an inverse relationship with the plurality of first dummy electrodes 9C.

When the wavelength of the surface acoustic wave is λ, the length of the uppermost first dummy electrode 9C is set to λ. The length of the lowermost first dummy electrode 9C is set to approximately 0. The length of the uppermost second dummy electrode 9F is set to approximately 0. The length of the lowermost second dummy 9F is set to λ.

As shown in FIG. 4 (as indicated by E), each of the plurality of first electrode fingers 9B includes first base side wide-width regions 10A. The first base side wide-width regions 10A are formed at base portions of the first electrode fingers 9B. As shown in FIG. 4 (as indicated by F), each of the plurality of first fingers 9B include first distal side wide-width regions 10B. The first distal side wide-width regions 10B are formed at distal side of the first electrode fingers 9B.

As shown in FIG. 4 (as indicated by F), each of the plurality of second electrode finger 9E includes second base side wide-width regions 10C. The second base side wide-width regions 10C are formed at base portions of the second electrode fingers 9E. As shown in FIG. 4 (as indicated by E), each of the plurality of second electrode finger 9E includes second distal side wide-width regions 10D. The second distal side wide-width regions 10D are formed at distal side the second electrode fingers 9E.

As shown in FIG. 4 (as indicated by E), the first base side wide-width regions 10A adjoin to the second distal side wide-width regions 10D of the adjacent second electrode finger 9E. As shown in FIG. 4 (as indicated by F), the second base side wide-width regions 10C adjoin to the first distal side wide-width regions 10B of the adjacent first electrode fingers 9B.

For example, the length L of the aperture length is set to between 0.50λ and 1.75λ when the wave length of the surface acoustic wave is λ in the first base side wide-width regions 10A, the first distal side wide-width regions 10B, the second base side wide-width regions 10C and the second distal side wide-width regions 10D. For example, the width W of the acoustic wave in the traveling direction is set to the width of the set magnification between 1.1 and 1.4 times in corresponding electrode finger. In the present embodiment, the length L of the aperture length is set to λ. The width W in the traveling direction of the acoustic wave is set to 1.2 times the width of the corresponding electrode finger.

Next, characteristics of the resonator 8 will be described with reference to FIG. 5. FIG. 5 is a diagram illustrating the characteristics of the resonator of the acoustic wave device according to the first embodiment and the resonator of the comparative example. The horizontal axis of FIG. 5 represents frequency MHz. The vertical axis of FIG. 5 represents conductance (dB).

In FIG. 5, a solid line Z1 is characteristics of the resonator 8 of the acoustic wave device 1 according to the first embodiment. The capacitance is set to 3.385 pF in the resonator 8. The number of pairs is set to 81.5 pairs. The aperture length is set to 20.4λ. The duty ratio (the ratio of the width of the electrode finger to the pitch of the electrode finger) is set to 50%. A dotted line Z2 is characteristics of the comparative example in which the inclined section of the bus bar and the wide-width regions of the electrode fingers are removed from the resonator 8 of the acoustic wave device 1 according to the first embodiment. In the comparative example, the capacitance, the number of pairs, the aperture length, and the duty ratio are the same as those of the resonator 8.

As shown in FIG. 5, in the dotted line Z2, the conductance is locally increased in the area M between the resonant frequency fr and the anti-resonant frequency fa. On the other hand, in the solid line Z1, the conductance is suppressed from locally increasing even in the area M between the resonance frequency fr and the anti-resonance frequency fa. This indicates that the transverse-mode spurious of the resonator 8 is more suppressed between the resonant frequency fr and the anti-resonant frequency fa.

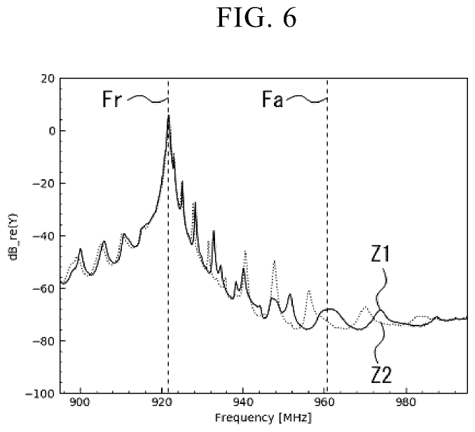

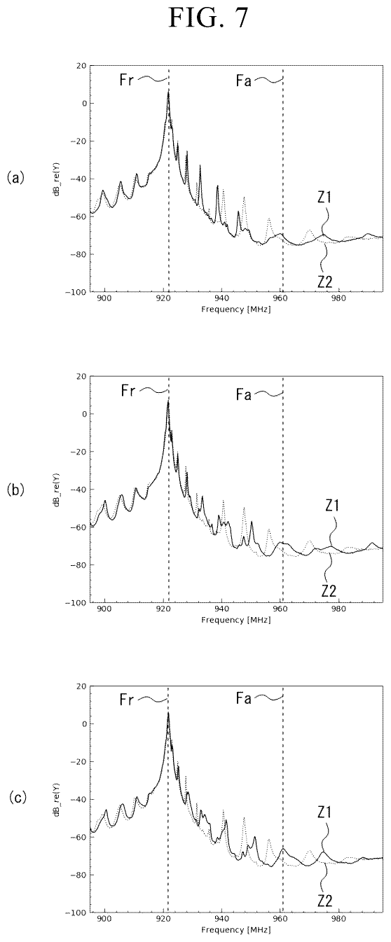

Next, the difference in characteristics due to the difference in the length of the dummy electrode will be described with reference to FIGS. 6 and 7. FIG. 6 is a diagram illustrating the characteristics of the resonator including bus bar with the same inclined section as the resonator of the acoustic wave device according to the first embodiment and no wide-width regions with the same length of the dummy electrode, and the resonator of the comparative example. FIG. 7 is a diagram illustrating the characteristics of the resonator including bus bar with the different inclined section from the resonator of the acoustic wave device according to the first embodiment and no wide-width regions with the different length of the dummy electrodes, and the resonator of the comparative example. The horizontal axis and the vertical axis of FIGS. 6 and 7 are the same as those of FIG. 5.

In FIG. 6, the solid line Z1 represents the characteristics of the resonator including bus bar with the same inclined section as the resonator 8 of the acoustic wave device according to the first embodiment and no wide-width regions with the same length of the dummy electrode. The capacitance is set to 3.537 pF in the resonator. The number of pairs is set to 103 pairs. The aperture length is set to 17.5λ. The duty ratio is set to 55%. The dotted line Z2 is characteristics of the comparative example in which the inclined section of the bus bar and the wide-width regions of the electrode finger are removed from the resonator 8 of the acoustic wave device 1 according to the first embodiment. In the comparative example, the capacity is set to 3.537 pF. The number of pairs is set to 100 pairs. The aperture length is set to 18.1λ. The duty ratio is set to 55%.

In FIG. 7, the solid line Z1 represents the characteristics of the resonator including bus bar with the different inclined section from the resonator 8 of the acoustic wave device according to the first embodiment and no wide-width regions with the different length of the dummy electrode. In the resonator 8, the capacitance, the number of pairs, the aperture length, and the duty ratio are the same as those of the resonator 8 in FIG. 6. The dotted line Z2 in FIG. 7 is the same as the dotted line Z2 in FIG. 6.

The length of the uppermost first dummy electrode 9C is set to 0.5λ in FIG. 7 part (a). The length of the lowermost second dummy 9F is set to 0.5λ. The length of the uppermost first dummy electrode 9C is set to 1.5λ in FIG. 7 part (b). The length of the lowermost second dummy 9F is set to 1.5λ. The length of the uppermost first dummy electrode 9C is set to 2.0λ in FIG. 7 part (c). The length of the lowermost second dummy 9F is set to 2.0λ.

As shown in FIG. 6, in the solid line Z1, the conductance is suppressed from locally increasing in the slightly lower frequency band than the anti-resonant frequency fa. This indicates that the transverse-mode spurious of the resonator corresponding to the solid line Z1 is suppressed in the slightly lower frequency band than the anti-resonant frequency fa.

As shown in FIG. 7, in the solid line Z1, the conductance is suppressed from locally extremely increasing in the slightly lower frequency band than the anti-resonant frequency fa. This indicates that the transverse-mode spurious of the resonator corresponding to the solid line Z1 is suppressed to some extent in the slightly lower frequency band than the anti-resonant frequency fa.

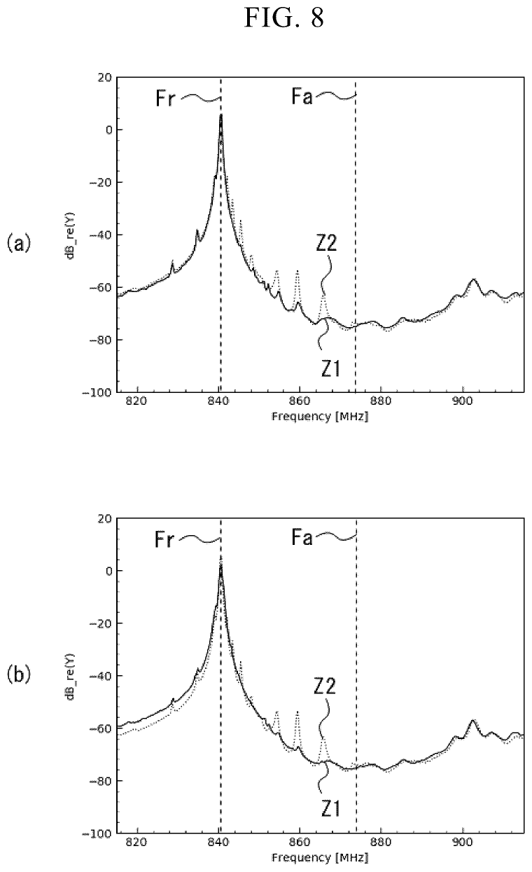

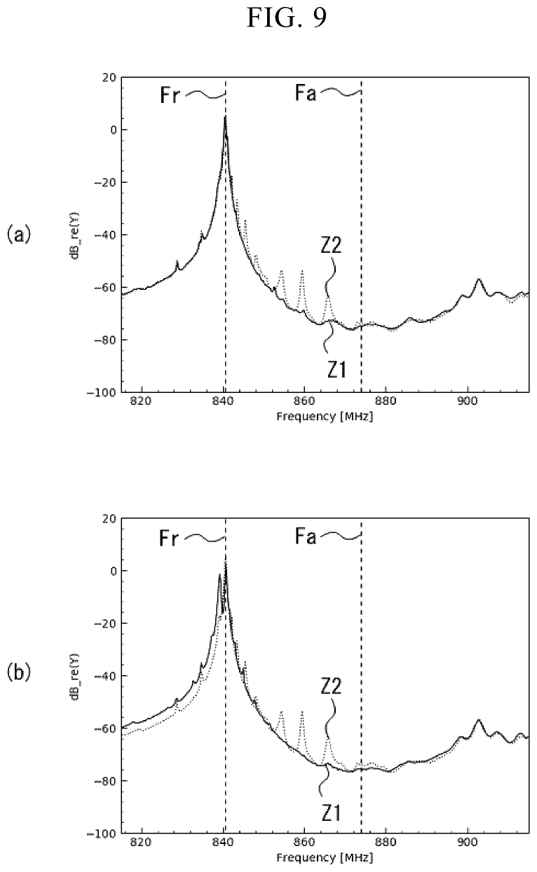

Next, the difference in characteristics due to the difference in the wide-width regions will be described with reference to FIGS. 8 and 9. In FIGS. 8 and 9 are diagrams illustrating the characteristics of the resonator including bus bar with the same inclined section as the resonator of the acoustic wave device according to the first embodiment and the different wide-width regions with the same length of the dummy electrode, and the resonator of the comparative example. The horizontal axis and the vertical axis of FIGS. 8 and 9 are the same as those of FIG. 5.

In FIGS. 8 and 9, the solid line Z1 represents the characteristics of the resonator including bus bar with the same inclined section as the resonator 8 of the acoustic wave device according to the first embodiment and the different wide-width regions with the same length of the dummy electrodes. In the resonator, the capacitance, the number of pairs, the aperture length, and the duty ratio are the same as those of the resonator in FIG. 5. The dotted line Z2 is the same as the dotted line Z2 corresponding to FIG. 5.

The length L of the aperture length of the wide-width regions is 0.50λ in FIG. 8 part (a). The width W of the acoustic wave in the traveling direction in the wide region is 1.25 times the width of the corresponding electrode finger. The length L of the aperture length of the wide-width regions is 0.75λ in FIG. 8 part (b). The width W of the acoustic wave in the traveling direction in the wide region is 1.20 times the width of the corresponding electrode finger. The length L of the aperture length of the wide-width regions is λ in FIG. 9 part (a). The width W of the acoustic wave in the traveling direction in the wide region is 1.15 times the width of the corresponding electrode finger. The length L of the aperture length of the wide-width regions is λ in FIG. 9 part (b). The width W of the acoustic wave in the traveling direction in the wide region is 1.25 times the width of the corresponding electrode finger.

As shown in FIGS. 8 and 9, in the solid line Z1, the conductance is suppressed from locally extremely increasing in the slightly higher frequency band than the resonant frequency fr. This indicates that the transverse-mode spurious of the resonator corresponding to the solid line Z1 is suppressed to some extent in the slightly higher frequency band than the resonant frequency fr.

According to the first embodiment described above, the first electrode fingers 9B include the first distal side wide-width regions 10B. The second electrode fingers 9E have the second distal side wide-width regions 10D. The plurality of first dummy electrodes 9C are formed so as to gradually shorten from one end portion to the other end portion of the first bus bar 9A. Therefore, transverse-mode spurious between the resonant frequency fr and the anti-resonant frequency fa can be suppressed more reliably.

The support substrate 3B is a polycrystalline substrate formed of silicon, alumina, spinel, or glass. Therefore, transverse-modes spurious between the resonant frequency fr and the anti-resonant frequency fa can be suppressed more reliably even in the resonator 8 in which the polycrystalline substrate is used.

The polycrystalline substrate as the support substrate 3B is C-axis oriented. Therefore, transverse-modes spurious between the resonant frequency fr and the anti-resonant frequency fa can be suppressed more reliably even in the resonator 8 in which the C-axis oriented polycrystalline substrate is used.

The low acoustic velocity layer 3C is disposed between the piezoelectric substrate 3A and the support substrate 3B. Therefore, transverse-modes spurious between the resonant frequency fr and the anti-resonant frequency fa can be suppressed more reliably even in the resonator 8 including the low acoustic velocity layer 3C.

The first electrode fingers 9B include the first base side wide-width regions 10A. The second electrode fingers 9E include the second base side wide-width regions 10C. Therefore, transverse-modes spurious between the resonant frequency fr and the anti-resonant frequency fa can be suppressed more reliably.

The first base side wide-width regions 10A adjoins to the second distal side wide-width regions 10D of the adjacent second electrode finger 9E. The second base side wide-width regions 10C adjoins to the first distal side wide-width regions 10B of the adjacent first electrode fingers 9B. Therefore, transverse-modes spurious between the resonant frequency fr and the anti-resonant frequency fa can be suppressed more reliably.

The plurality of second dummy electrodes 9F are formed so as to gradually lengthen from one end portion to the other end portion of the second bus bar 9D in an inverse relationship with the plurality of first dummy electrodes 9C. Therefore, transverse-modes spurious between the resonant frequency fr and the anti-resonant frequency fa can be suppressed more reliably.

The length L of the aperture length is set to between 0.50λ and 1.75λ in the first base side wide-width regions 10A, the first distal side wide-width regions 10B, the second base side wide-width regions 10C and the second distal side wide-width regions 10D. Therefore, transverse-modes spurious between the resonant frequency fr and the anti-resonant frequency fa can be suppressed more reliably.

The length L of the aperture length may be set to between 0.50λ and 1.75λ in at least one of the first base side wide-width regions 10A, the first distal side wide-width regions 10B, the second base side wide-width regions 10C and the second distal side wide-width regions 10D. In this case, transverse-modes spurious between the resonant frequency fr and the anti-resonant frequency fa can be suppressed to some extent.

The width W of the acoustic wave in the traveling direction is set to the width of the set magnification between 1.1 and 1.4 times in corresponding electrode finger in the first base side wide-width regions 10A, the first distal side wide-width regions 10B, the second base side wide-width regions 10C and the second distal side wide-width regions 10D. Therefore, transverse-modes spurious between the resonant frequency fr and the anti-resonant frequency fa can be suppressed more reliably.

The width W of the acoustic wave in the traveling direction is set to the width of the set magnification between 1.1 and 1.4 times in corresponding electrode finger in at least one of the first base side wide-width regions 10A, the first distal side wide-width regions 10B, the second base side wide-width regions 10C and the second distal side wide-width regions 10D. In this case, transverse-modes spurious between the resonant frequency fr and the anti-resonant frequency fa can be suppressed more reliably.

### Second Embodiment

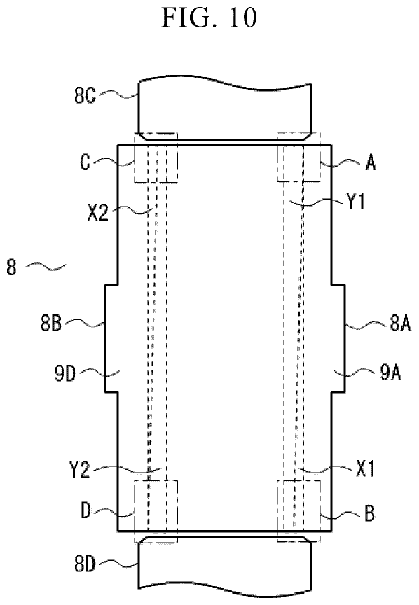

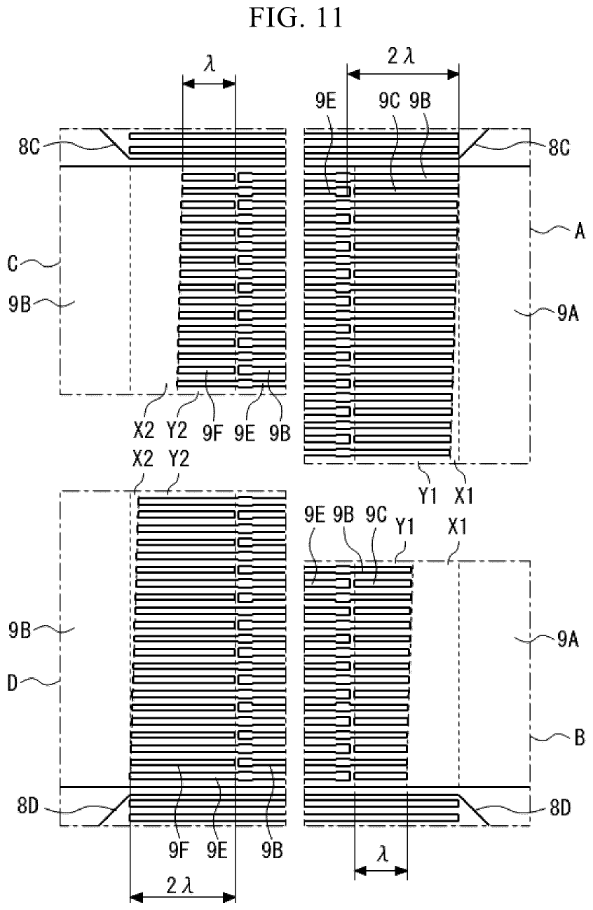

FIG. 10 is a diagram illustrating an example of a resonator of the acoustic wave device according to the second embodiment. FIG. 11 is an enlarged view of a portion A and B and C and D of FIG. 10. The same or corresponding parts with the first embodiment to third embodiment are denoted by the same reference numerals. Duplicate descriptions of such portions may be simplified or omitted.

As shown in FIG. 10, in the second embodiment, the first dummy electrode region Y1 and the second dummy electrode region Y2 are different from those in the first embodiment.

Specifically, as shown in FIG. 11, when the wave length of the surface acoustic wave is λ, the length of the uppermost first dummy electrode 9C is set to 2λ in the second embodiment. The length of the lowermost first dummy electrode 9C is set to λ. The length of the uppermost second dummy 9F is set to λ. The length of the lowermost second dummy electrode 9F is set to 2λ.

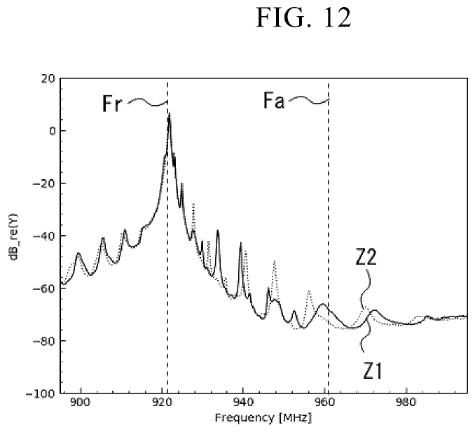

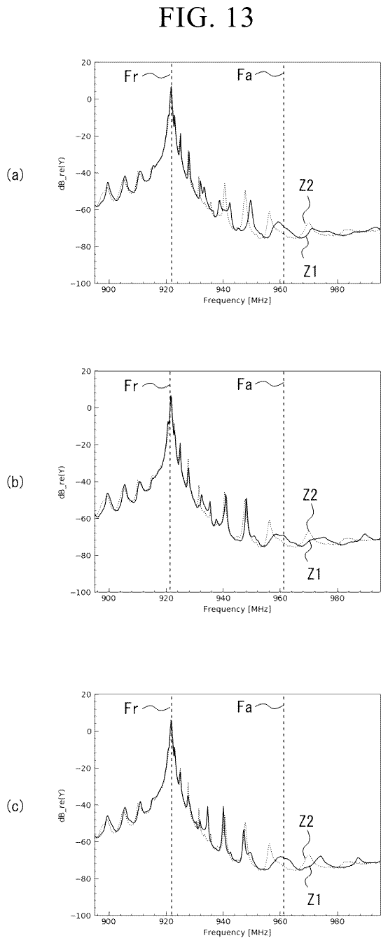

Next, the difference in characteristics due to the difference in the length of the dummy electrode will be described with reference to FIGS. 12 and 13. FIG. 12 is a diagram illustrating the characteristics of the resonator including bus bar with the same inclined section as the resonator of the acoustic wave device according to the second embodiment and no wide-width regions with the same length of the dummy electrodes, and the resonator of the comparative example. FIG. 13 is a diagram illustrating the characteristics of the resonator including bus bar with the different inclined section from the resonator of the acoustic wave device according to the second embodiment and no wide-width regions with the different length of the dummy electrodes, and the resonator of the comparative example. The horizontal axis and the vertical axis of FIGS. 12 and 13 are the same as those of FIG. 5

In FIG. 12, the solid line Z1 is the characteristics of the resonator including bus bar with the same inclined section as the resonator 8 of the acoustic wave device according to the second embodiment and no wide-width regions with the same length of the dummy electrodes. In the resonator, the capacitance, the number of pairs, the aperture length, and the duty ratio are the same as those of the resonator in FIG. 6. The dotted line Z2 is characteristics of the comparative example in which the inclined section of the bus bar and the wide-width regions of the electrode finger are removed from the resonator 8 of the acoustic wave device 1 according to the second embodiment. In the resonator of the comparative example, the capacitance, the number of pairs, the aperture length, and the duty ratio are the same as those of the resonator of the comparative example in FIG. 6.

In FIG. 13, the solid line Z1 is the characteristics of the resonator including bus bar with the different inclined section from the resonator 8 and no wide-width regions with the different length of the dummy electrodes. In the resonator 8, the capacitance, the number of pairs, the aperture length, and the duty ratio are the same as those of the resonator 8 in FIG. 6. The dotted line Z2 is the same as the dotted line Z2 in FIG. 12.

The length of the lowermost first dummy electrode 9C is set to 0.25λ in FIG. 13 part (a). The length of the uppermost second dummy 9F is set to 0.25λ. The length of the lowermost first dummy electrode 9C is set to 0.5 \ in FIG. 13 part (b). The length of the uppermost second dummy 9F is set to 0.5λ. The length of the lowermost first dummy electrode 9C is set to 0.75λ in FIG. 13 part (c). The length of the uppermost second dummy 9F is set to 0.75λ.

As shown in FIG. 12, in the solid line Z1, the conductance is suppressed from locally increasing in the slightly lower frequency band than the anti-resonant frequency fa. This indicates that the transverse-mode spurious of the resonator corresponding to the solid line Z1 is suppressed in the slightly lower frequency band than the anti-resonant frequency fa.

As shown in FIG. 13, in the solid line Z1, the conductance is suppressed from locally extremely increasing in the slightly lower frequency band than the anti-resonant frequency fa. This indicates that the transverse-mode spurious of the resonator corresponding to the solid line Z1 is suppressed to some extent in the slightly lower frequency band than the anti-resonant frequency fa.

According to the second embodiment described above, the length of the uppermost first dummy electrode 9C is set to 2λ. The length of the lowermost first dummy electrode 9C is set to λ. The length of the uppermost second dummy electrode 9F is set to λ. The length of the lowermost second dummy 9F is set to 2λ. Therefore, spurious between the resonant frequency fr and the anti-resonant frequency fa can be suppressed more reliably.

Note that the dummy electrode connected to the other end of the first bus bar 9A or one end of the second bus bar 9D may have a length of a set magnification between 0.125 and 0.500 times to the length of the dummy electrode connected to one end of the first bus bar 9A or the other end of the second bus bar 9D. In this case spurious characteristics between the resonant frequency fr and the anti-resonant frequency fa can be suppressed to some extent.

### Third Embodiment

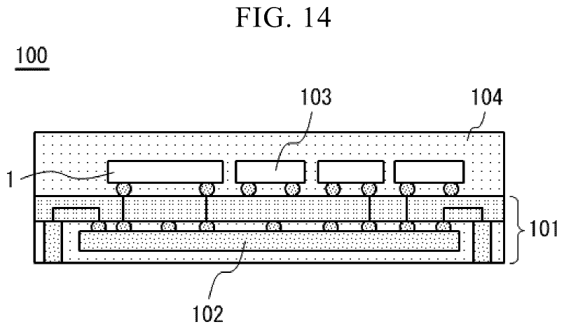

FIG. 14 is a sectional view of a module to which the acoustic wave device according to the third embodiment is applied. The same or corresponding parts with the first embodiment are denoted by the same reference numerals. Duplicate descriptions of such portions may be simplified or omitted.

A module 100 includes a wiring substrate 101, an integrated circuit component 102, the acoustic wave device 1, an inductor 103, and a sealing portion 104 in FIG. 14.

The wiring substrate 101 is equivalent to the wiring substrate 2 of the first embodiment. The integrated circuit component 102 is mounted inside the wiring substrate 101. The integrated circuit component 102 includes a switching circuit and a low noise amplifier. The acoustic wave device 1 is mounted on the main surface of the wiring substrate 101. The inductor 103 is mounted on the main surface of the wiring substrate 101. The inductor 103 is implemented for impedance matching. For example, the inductor 103 is an Integrated Passive Device (IPD). The sealing portion 104 seals a plurality of electronic components including the acoustic wave device 1

According to the third embodiment described above, the module 100 includes the acoustic wave device 1. Therefore, the module 100 including the acoustic wave device 1 in which the transverse-mode spurious between the resonant frequency fr and the anti-resonant frequency fa is suppressed can be obtained.

While several aspects of at least one embodiment have been described, it is to be understood that various modifications and improvements will readily occur to those skilled in the art. Such modifications and improvements are intended to be part of the present disclosure and are intended to be within the scope of the present disclosure.

It is to be understood that the embodiments of the methods and apparatus described herein are not limited in application to the structural and ordering details of the components set forth in the foregoing description or illustrated in the accompanying drawings. Methods and apparatus may be implemented in other embodiments or implemented in various manners. Specific implementations are given here for illustrative purposes only and are not intended to be limiting.

The phraseology and terminology used in the present disclosure are for the purpose of description and should not be regarded as limiting. The use of “including,” “comprising,” “having,” and variations thereof herein means the inclusion of the items listed hereinafter and equivalents thereof, as well as additional items.

The reference to “or” may be construed so that any term described using “or” may be indicative of one, more than one, and all of the terms of that description.

References to front, back, left, right, top, bottom, and side are intended for convenience of description. Such references are not intended to limit the components of the present disclosure to any one positional or spatial orientation. Accordingly, the foregoing description and drawings are by way of example only.

What is claimed is:

1. An acoustic wave device comprising:
a piezoelectric substrate;
a support substrate, a first side of the support substrate bonded on the piezoelectric substrate; and
a resonator formed on a second side of the support substrate on the piezoelectric substrate generates main-mode wave and transverse-mode wave when power is applied,
wherein the resonator comprises a first bus bar, a second bus bar opposed to the first bus bar, a plurality of first electrode fingers connected to a side of the second bus bar in the first bus bar, a plurality of second electrode fingers connected to a side of the first bus bar in the second bus bar, a plurality of first dummy electrodes connected to the side of the second bus bar in the first bus bar and opposed to the plurality of second electrode fingers, and a plurality of second dummy electrodes connected to the side of the first bus bar in the second bus bar and opposed to the plurality of first electrode fingers,
wherein distal ends of the plurality of first electrode fingers comprise first distal side wide-width regions, distal ends of the plurality of second electrode fingers comprise second distal side wide-width regions, and the plurality of first dummy electrodes are formed so as to be gradually shorten from one end portion to an other end portion of the first bus bar.

2. The acoustic wave device according to claim 1, wherein the support substrate comprises a polycrystalline substrate formed of silicon, alumina, spinel, or glass.

3. The acoustic wave device according to claim 2, wherein the polycrystalline substrate comprises C-axis oriented.

4. The acoustic wave device according to claim 1 comprises a low acoustic velocity layer disposed between the piezoelectric substrate and the support substrate.

5. The acoustic wave device according to claim 1, wherein base portions of the plurality of first electrode fingers comprise first base side wide-width regions and base portions of the plurality of the second electrode fingers comprise second base side wide-width regions.

6. The acoustic wave device according to claim 5, wherein the first base side wide-width regions of the first electrode fingers adjoins an adjacent the second distal side wide-width regions of the second electrode fingers and the second base side wide-width regions of the second electrode fingers adjoins an adjacent the first distal side wide-width regions of the first electrode fingers.

7. The acoustic wave device according to claim 1, wherein the plurality of second dummy electrodes are formed so as to gradually lengthen from one end portion to an other end portion of the second bus bar in an inverse relationship with the plurality of first dummy electrodes.

8. The acoustic wave device according to claim 1, wherein the first distal side wide-width regions or the second distal side wide-width regions have length between 0.50λ and 1.75λ in direction of aperture length.

9. The acoustic wave device according to claim 1, wherein the first distal side wide-width regions or the second distal side wide-width regions have width of magnification between 1.1 and 1.4 times in a corresponding width of electrode finger in direction of an acoustic wave propagation.

10. The acoustic wave device according to claim 1, wherein a dummy electrode connected to the other end of the first bus bar or one end of the second bus bar is formed to have the length of a set magnification between 0.125 and 0.500 times to the length of a dummy electrode connected to one end of the first bus bar or the other end of the second bus bar.

11. A module comprising the acoustic wave device according to claim 1.
